(19) United States
(12) Patent Application Publication
(10) Pub. No.: US 2024/0222391 A1
(43) Pub. Date: Jul. 4, 2024

(54) DISPLAY APPARATUS AND MANUFACTURING METHOD OF THE SAME

(71) Applicant: LG Display Co., Ltd., Seoul (KR)

(72) Inventors: Jongsoo HAN, Paju-si (KR); Sanghak SHIN, Paju-si (KR); Hyoungsun PARK, Seoul (KR); Hyunseok NA, Hwaseong-si (KR); Pyungho CHOI, Seoul (KR); Hyunchyol SHIN, Seoul (KR); Seongsoo CHO, Seoul (KR)

(73) Assignee: LG Display Co., Ltd., Seoul (KR)

(21) Appl. No.: 18/540,413

(22) Filed: Dec. 14, 2023

(30) Foreign Application Priority Data
Dec. 28, 2022 (KR) 10-2022-0187555

(51) Int. Cl. H01L 27/12; H01L 25/16; H10K 59/12; H10K 59/131

(52) U.S. Cl. CPC H01L 27/124; H01L 25/167; H01L 27/1259; H10K 59/1201; H10K 59/131

(57) ABSTRACT

A display apparatus can include an adhesive layer disposed on the substrate, a pixel driver chip disposed on the adhesive layer and including a plurality of pads disposed on an upper surface thereof, a planarization surrounding side surfaces of the pixel driver chip, first wires disposed on the planarization layer, and pad contact layers disposed on a plurality of pads of the pixel driver chip. Here, the pad contact layers and the first wires can have the same thickness and can be composed of the same conductive material layer.

### CROSS-REFERENCE TO RELATED APPLICATION

This application claims priority to Korean Patent Application No. 10-2022-0187555 filed in the Republic of Korea on Dec. 28, 2022, which is hereby expressly incorporated by reference into the present application.

### BACKGROUND

### Technical Field

The present disclosure relates to a display apparatus and a manufacturing method of the same. More particularly, the present disclosure is directed to a display apparatus that can prevent damage to pads of a pixel driver chip while simplifying a manufacturing process, and to a method of manufacturing such display apparatus.

### Discussion of the Related Art

Examples of a flat panel display device that are widely used include a liquid crystal display apparatus, an organic light emitting display apparatus, an inorganic light emitting display apparatus, and a quantum dot display apparatus.

Generally, a flat panel display device can include two substrates that face each other where on the substrates is a thin film transistor (TFT) array substrate for driving the pixels of the display device. The TFT array substrate can include an array of TFTs and other elements (e.g., planarization layer) that are disposed to drive the pixels.

Recently, display devices in which the TFT array is replaced with pixel driver chips are being developed to realize a high resolution for the display devices. Such pixel driver chips can be referred to as micro driver chips and can drive light emitting diodes (LEDs).

### SUMMARY OF THE DISCLOSURE

The inventors of the present application have discovered and invented a display apparatus and a method of manufacturing the same, which offer improvements to the existing pixel driver chip technology.

Particularly, pixel driver chips can be manufactured by a separate manufacturing process and then mounted on a substrate of a display apparatus by a transfer process. Such pixel driver chips can have various input/output pads. In order to protect the input/output pads, the pixel driver chip can include a passivation film covering the input/output pads. After the pixel driver chip is transferred on the substrate of the display apparatus, a planarization layer surrounding side surfaces of the pixel driver chip can be formed and single-layer or multi-layer wires can be formed on the planarization layer.

A process of forming wires on the planarization layer can include depositing a conductive material layer on the planarization layer, patterning the conductive material layer by using a photolithography process and a dry etching process, and exposing the input/output pads by removing a passivation film of the pixel driver chip through the photolithography process and a wet etching process. In this process, when there is no etching selectivity between the conductive material layer and the passivation film during the dry etching process, there can be a limitation in that not only the passivation film but also the input/output pads of the pixel driver chip can be etched in a specific area of the substrate where the etching rate is higher during the dry etching process, for example, in a central area of the substrate.

Accordingly, the inventors of the present disclosure invented a display apparatus and a manufacturing method of the same that can prevent damage to the input/output pads of a pixel driver chip, even when there is no etching selectivity between a conductive material layer and a passivation film during a dry etching process for forming wires.

As such, one objective of the embodiments of the present disclosure is to provide a display apparatus that can prevent damage to pads of a pixel driver chip when forming wires and to simplify a manufacturing process of the display apparatus.

Aspects and objects according to the present disclosure are not limited to the above ones, and other aspects and advantages that are not mentioned above can be clearly understood from the following description and can be more clearly understood from the embodiments set forth herein by people skilled in the art.

A display apparatus according to embodiments of the present disclosure can include a substrate: an adhesive layer disposed on the substrate; a pixel driver chip disposed on the adhesive layer and comprising a plurality of pads disposed on an upper surface thereof; a planarization surrounding side surfaces of the pixel driver chip; pad contact layers disposed on a plurality of pads of the pixel driver chip; and first wires disposed on the planarization layer. Here, the pad contact layers, and the first wires can have the same thickness and are configured of the same conductive material layer.

A manufacturing method of a display apparatus according to embodiments of the present disclosure can include forming an adhesive layer on a substrate; mounting a pixel driver chip comprising a plurality of pads on the adhesive layer; forming a planarization layer surrounding side surfaces of the pixel driver chip; depositing a conductive material layer on the planarization layer and the pixel driver chip; and simultaneously forming pad contact layers disposed on the plurality of pads of the pixel driver chip and first wires disposed on the planarization layer by patterning the conductive material layer.

Detailed descriptions of other embodiments are included in the following description and the accompanying drawings.

According to the embodiments of the present disclosure, the input/output pads of the pixel driver chip may not be damaged during a dry etching process for forming wires on a planarization layer in the display apparatus.

According to embodiments of the present disclosure, the photolithography process for removing the passivation film of the pixel driver chip can be omitted, thereby simplifying the manufacturing process of the display apparatus and reducing the manufacturing cost.

In addition to the above-described effects, specific effects of the present invention will be described together with the following detailed description for implementing the present invention.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a sectional view showing a display apparatus according to an embodiment of the present disclosure;

FIG. 2 is a sectional view showing a display apparatus according to another embodiment of the present disclosure; and

FIGS. 3 to 12 are plane views and cross-sectional views showing a method of manufacturing the display apparatus according to an embodiment of the present disclosure.

### DETAILED DESCRIPTION OF THE EMBODIMENTS

The above objects, features, advantages and methods to achieve them will be described later in detail with reference to the accompanying drawings, and accordingly, those skilled in the art to which the present invention belongs will be able to easily implement the technical idea of the present invention. In describing the present invention, if it is determined that the detailed description of the known technology related to the present invention can unnecessarily obscure the subject matter of the present invention, the detailed description will be omitted.

Hereinafter, preferred embodiments according to the present invention will be described in detail with reference to the accompanying drawings. In the drawings, the same reference numerals are used to indicate the same or similar components. The present disclosure should be construed to extend to any alterations, equivalents and substitutes in addition to those which are particularly set out in the accompanying drawings. Terms of respective elements used in the following description are terms defined taking into consideration of the functions obtained in the present invention. Therefore, these terms do not limit technical elements in the present invention. Further, the defined terms of the respective elements will be called other terms in the art. Terminology that is used in the present disclosure is limited to only for embodiments herewith but made only to make it easy to understand the present disclosure. A singular representation can include a plural representation unless it represents a definitely different meaning from the context. Terms such as “comprise,” “include” or “has” are used herein and should be understood that they are intended to indicate an existence of several components, functions or steps, disclosed in the specification, and it is also understood that greater or fewer components, functions, or steps can likewise be utilized. Further, terms such as “invention” and “disclosure” carry the same meaning and thus are interchangeably used herein.

In understanding the components, it should be understood as including the error range even if there is no separate explicit description.

In descriptions of temporal relationships, for example, temporal precedent relationships between two events such as “after”, “subsequent to”, “before”, etc., another event can occur therebetween unless “directly after”, “directly subsequent” or “directly before” is indicated. Further, the terms such as “above,” “over,” “on,” “under,” “below,” “between,” “adjacent,” etc. are used herein to merely refer to a relative position of one layer/element to another layer/element, where no layer/element or one or more additional layers/elements can be disposed between those two layers/elements.

It will be understood that although the terms first, second, etc. can be used herein to describe various elements, these elements should not be limited by these terms. These terms are generally only used to distinguish one element from another and may not define order or sequence.

In the drawings, identical reference numerals can denote identical or similar components.

For the sake of brief description with reference to the drawings, the sizes, thickness and profiles of the elements illustrated in the accompanying drawings can be exaggerated or reduced and it should be understood that the embodiments presented herein are not limited by the accompanying drawings.

Features of various embodiments can be partially or entirely combined with each other, and various connections and driving are possible. Further, embodiments can be implemented independently or implemented in a related relationship.

Hereinafter, a display apparatus according to embodiments of the present disclosure will be described referring to the accompanying drawings. All the components of each display apparatus according to all embodiments of the present disclosure are operatively coupled and configured.

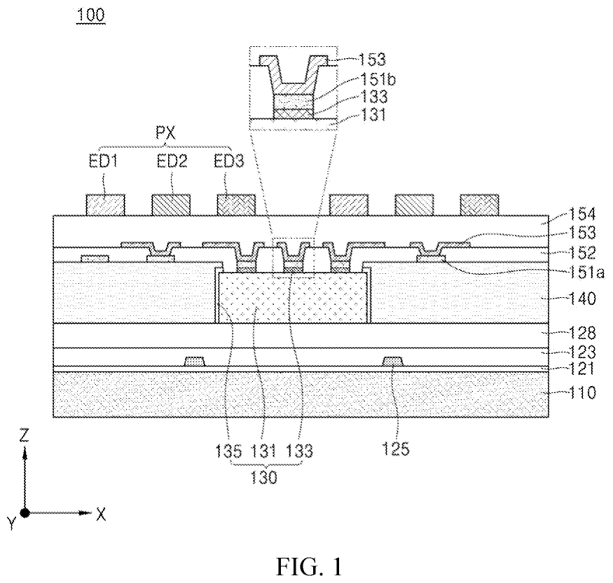

FIG. 1 is a sectional view showing a display apparatus 100 according to an embodiment of the present disclosure.

Referring to FIG. 1, the display apparatus 100 according to the embodiment of the present disclosure can include a plurality of buffer layers 121 and 123 disposed on a substrate 110, a plurality of alignment marks 125, an adhesive layer 128 disposed on the buffer layers 121 and 123, a pixel driver chip 130, a planarization layer 140, a plurality of wires 151a and 153, a plurality of insulating layers 152 and 154 disposed on the planarization layer, and a plurality of light emitting elements ED1, ED2 and ED3 disposed on the insulating layers 152 and 154. The plurality of wires 151a and 153 can be conductive patterns, conductive lines or other elements that provide electrical conduction/connection.

The substrate 110 can be made of plastic with flexibility or other flexible material. For example, the substrate 110 can have a single-layer or multi-layer structure made of polyethylene terephthalate, polyethylene naphthalate, polycarbonate, polyethersulfone, polyarylate, polysulfone, cyclic-olefin copolymer or the like, but the embodiment is not limited thereto. The substrate 110 can be made of glass.

Among the buffer layers 121 and 123, the first buffer layer 121 can be disposed on the substrate 110. For example, the first buffer layer 121 can be made of an insulating material such as a silicon nitride, a silicon oxide, a silicon oxynitride, etc., but the embodiment is not limited thereto.

The alignment marks 125 can be disposed on the first buffer layer 121. The alignment marks 125 can guide a mounting position of the pixel driver chip 130 during a transfer process. For example, the alignment marks 125 can be made of metal but the embodiment is not limited thereto such as a non-conductive material.

The second buffer layer 123 can be disposed on the first buffer layer 121 and the alignment marks 125. For example, the second buffer layer 123 can be made of an insulating material such as a silicon nitride, a silicon oxide or a silicon oxynitride, but the embodiment is not limited thereto. The second buffer layer 123 can be thicker than the first buffer layer 121. The first and second buffer layers 121 and 123 can be made of a same material or different materials.

The adhesive layer 128 can be disposed on the second buffer layer 123. For example, the adhesive layer 128 can be made of acrylic resin, silicon resin or the like, but the embodiment is not limited thereto.

The pixel driver chip 130 can be disposed on the adhesive layer 128. The pixel driver chip 130 can be positioned in a display area of the display apparatus 100. FIG. 1 shows that one pixel driver chip 130 is disposed on the adhesive layer 128 as one example but the display apparatus can include a plurality of pixel driver chips 130 disposed on the adhesive layer 128. The plurality of pixel driver chips 130 can be arranged in a matrix type including a plurality of rows and a plurality of columns in the display area of the display apparatus 100. For instance, the plurality of pixel drive chips 130 can be arranged in a matrix configuration or other suitable configuration.

The pixel driver chap 130 can be configured to drive and switch the plurality of light emitting elements ED1, ED2 and ED3 disposed in at least one pixel PX of the display area. As an example, the display area of the display apparatus 100 can include a plurality of pixels PX where one pixel drive chips 130 can be provided for each of the pixels PX or for groups of pixels PX, and can drive one or more light emitting elements in the corresponding pixel(s) PX.

For instance, the pixel driver chip 130 can drive and switch the plurality of light emitting elements ED1, ED2 and ED3 disposed in one or more of the plurality of pixels PX disposed in the display area. As mentioned, the plurality of pixels PX can be arranged in the display area as a matrix form including a plurality of rows and a plurality of columns. For example, each of the pixel driver chips 130 can drive and switch a plurality of light emitting elements disposed in 16×16 pixels, that is, 256 pixels. The pixel driver chip 130 can be referred to as a microdriver chip. For example, the pixel driver chip 130 can have a size of 1 μm to 50 μm or 1 μm to 300 μm in a horizontal direction (e.g., X-axis direction or Y-axis direction).

The pixel driver chip 130 can include an element layer 131, a plurality of pads 133 and a passivation film 135. The element layer 131 can include a circuit for driving and switching one or more light emitting elements. The element layer 131 can include a digital circuit, an analog circuit and the like. The element layer 131 can include driving transistors, switching transistors and storing capacitors. The element layer 131 can include a plurality of circuit units. Each of the circuit units can include at least one driving transistor, at least one switching transistor and at least one storing capacitor. The element layer 131 can be fabricated on a single crystal semiconductor substrate by using MOSFET manufacturing processes, for example.

The plurality of pads 133 can include various input pads and output pads. The plurality of pads 133 can include a pad connected with the light emitting element(s), a pad connected with a high potential voltage line, a pad connected with a low potential voltage line, a pad connected to a data signal line, a pad connected with a scan signal line, a pad connected with a reference voltage line and the like, but the embodiment is not limited thereto.

The plurality of pads 133 can have a single-layer or multi-layer structure configured of a conductive material. The plurality of pads 133 can be a single-layer or multi-layer structure including Ti, Ta, Al, Cu, TiN, TaN or the like or a combination thereof. The plurality of pads 133 can have a Ti/TiN/Ti structure, for example.

The passivation film 135 can cover side surfaces of the element layer 131. The passivation film 135 can cover an edge area of an upper surface of the element layer 131 on which the plurality of pads 133 are disposed, but may expose the remaining upper surface (inner upper surface) of the element layer 131. In another example, the passivation film 135 may not cover the upper surface of the element layer 131 at all, but can cover only the side surfaces of the device layer 13. In still an example, the passivation film 135 can cover only an edge area of the upper surface of the element layer 131 and may not cover the remaining upper surface and the side surfaces of the element layer 131. In another example, the passivation film 135 may not cover the upper surface and side surfaces of the element layer 131.

The passivation film 135 can be made of aluminum oxide AlOx, but the embodiment is not limited thereto.

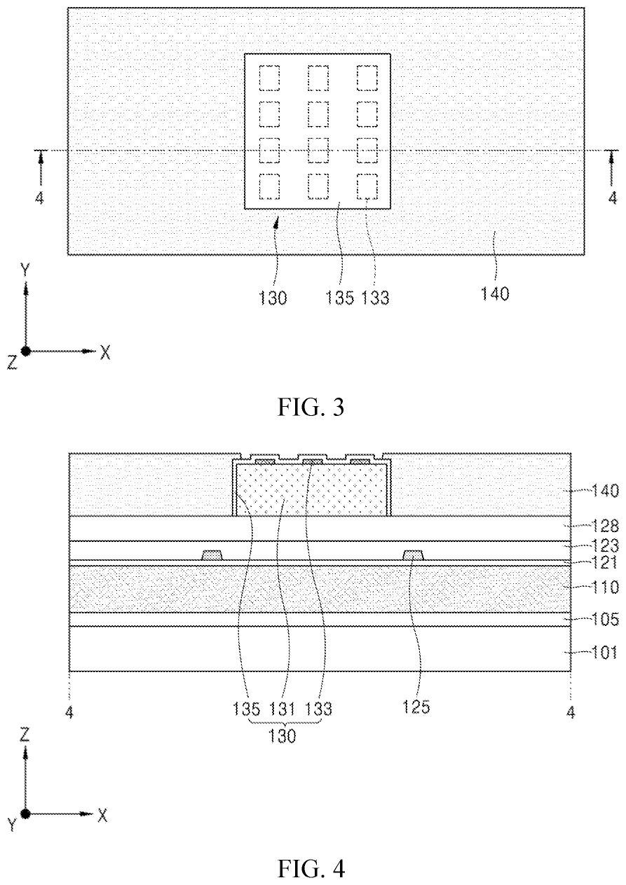

The pixel driver chip 130 can be fabricated through a separate manufacturing process, and can be disposed on the adhesive layer 128 by a transfer process. Before the pixel driver chip 130 is disposed on or moved to the adhesive layer 128 of the display apparatus 100, the passivation film 135 can be covering the plurality of pads 133 and the entire upper surface of the element layer 131 as well as the side surfaces of the element layer 131 to protect the plurality of pads 133 (see FIGS. 3 and 4). In an example, before the pixel driver chip 130 is disposed on or moved to the adhesive layer 128, the passivation film 135 can cover the plurality of pads 133 and the upper surface of the element layer 131 to protect the plurality of pads 133, not the side surfaces of the element layer 131.

The planarization layer 140 surrounding the side surfaces of the pixel driver chip 130 can be disposed on the adhesive layer 128, and exposes the upper surface (in its entirety or all the areas excluding the edge area) of the element layer 131. The planarization layer 140 may not cover the plurality of pads 133. The planarization layer 140 can be disposed on the passivation film 135 so that it covers only the edge area of the upper surface of the element layer 131, which is covered by the passivation film 135. In another example, the planarization layer 140 may not cover the upper surface of the element layer 131 and the plurality of pads 133. The planarization layer 140 can be made of an organic material. For example, the planarization layer 140 can be made of photosensitive photo acryl or photosensitive polyimide, but the embodiment is not limited thereto.

The first wires (or first conductive patterns) 151a can be disposed on the planarization layer 140. Further, pad contact layers 151b can be disposed on the plurality of pads 133 of the pixel driver chip 130. The pad contact layers 151b directly disposed on the plurality of pads 133 may not cover the side surfaces of the plurality of pads 133. The pad contact layers 151b directly disposed on the plurality of pads 133 can have the same size or substantially the same size as the plurality of pads 133. The first wires 151a and the pad contact layer 151b can have the same thickness and/or can be made of the same conductive material layer. The first wires 151a and the pad contact layers 151b can each be configured of a single-layer or multi-layer structure of Ti, Ta, Al, Cu, TiN, TaN and the like or a combination thereof. The first wires 151a and the pad contact layers 151b can each have a Ti/Al/Ti structure, for example. The pad contact layers 151b can be formed with the thickness of 500 nm to 900 nm.

The first insulating layer 152 covering the first wires 151a and the pad contact layers 151b can be disposed on the planarization layer 140 and the pixel driver chip 130. For example, the first insulating layer 152 can be made of photosensitive photo acryl or photosensitive polyimide, but the embodiment is not limited thereto.

The second wires (or second conductive patterns) 153 can be disposed on the first insulating layer 152. The second wires 153 can be disposed on the first insulating layer 152. The second wires 153 can be connected with the first wires 151a and the pad contact layers 151b via the first insulating layer 152. The second wires 153 can be in direct contact with the first wires 151a and the pad contact layers 151b. Some of the second wires 153 can be connected with the plurality of pads 133 via the pad contact layers 151b. The second wires 153 can have a single-layer or multi-layer structure of Ti, Ta, Al, Cu, TiN, TaN and the like or a combination thereof. For example, the second wires 153 can have a Ti/Al/Ti structure. The thickness of the second wires 153 can be 500 nm to 900 nm. Accordingly, the sum of the thicknesses of the pad contact layer 151b and the second wire 153 disposed on each pad 133 can be 1,000 nm to 1,800 nm. Similarly, the sum of the thicknesses of the first wire 151a and the second wire 153 disposed on the planarization layer 140 can be 1,000 nm to 1,800 nm.

The second insulating layer 154 can be disposed on the first insulating layer 152 to cover the second wires 153. For example, the second insulating layer 154 can be made of photo acryl or photosensitive polyimide, but the embodiment is not limited thereto.

The plurality of light emitting elements ED1, ED2 and ED3 can be disposed on the second insulating layer 154. In the embodiment, at least one wire and at least one insulating layer can be additionally disposed between the second insulating layer 154 and the plurality of light emitting elements ED1, ED2 and ED3. The light emitting elements ED1, ED2 and ED3 can be driven (e.g., switched on and off) by the pixel driver chip 130 (e.g., by being electrically connected to the element layer 131 via the pads 133, the pad contact layer 151b and the second wires 153).

In the display area of the display apparatus 100, the plurality of pixels PX aligned in a matrix shape including a plurality of rows and a plurality of columns can be disposed. Each of the pixels PX can include a plurality of light emitting elements ED1, ED2 and ED3 emitting different colors, respectively, but a different number of light emitting elements can be disposed for each pixel PX. The plurality of light emitting elements ED1, ED2 and ED3 can be connected with the pixel driver chip 130. Each of the light emitting elements ED1, ED2 and ED3 can be connected with one of the pads 133. For instance, if there are three light emitting elements in a pixel, then three pads 133 can be provided to correspond respectively to the three light emitting elements; however, other variations are possible.

For example, the plurality of light emitting elements ED1, ED2 and ED3 can include three light emitting elements emitting a red light, a green light and a blue light, respectively, but the embodiment is not limited thereto. In an embodiment, the plurality of light emitting elements can include four light emitting elements emitting a red light, a green light, a blue light and a yellow light.

The plurality of light emitting elements ED1, ED2 and ED3 can be inorganic light emitting diodes or organic light emitting diodes.

As the light emitting elements ED1, ED2 and ED3, the inorganic light emitting diodes can have a size of 1 to 100 μm, 1 to 50 μm, or 1 to 20 μm in a horizontal direction (e.g., X-axis direction or Y-axis direction). The inorganic light emitting diode can be or can be referred to as a micro light emitting diode (micro LED). The inorganic light emitting diode can include a p-doped semiconductor layer, an n-doped semiconductor layer and an active layer (e.g., one or more quantum well layers) disposed between the two semiconductor layers. The inorganic light emitting diode can include a first electrode connected with the p-doped semiconductor layer and a second electrode connected with the n-doped semiconductor layer. The inorganic light emitting diodes can be fabricated by using group II-VI or III-V compound semiconductors. The inorganic light emitting diode can be manufactured by a separate manufacturing process and disposed on the adhesive layer 128 by a transfer process.

In a variation, as the light emitting elements ED1, ED2 and ED3, the organic light emitting diode can include a hole injection layer, a hole transport layer, an organic light emitting layer, an electron transport layer and an electron injection layer. The organic light emitting diode can include a first electrode connected with the hole injection layer and a second electrode connected with the electron injection layer. The organic light emitting diode can be directly formed on the second insulating layer 154 by a deposition process, a photolithography process, an etching process or the like.

The display apparatus 100 can further include other components to display images. For instance, additional layer(s) can be disposed on the second insulating layer 154 and/or the light emitting elements.

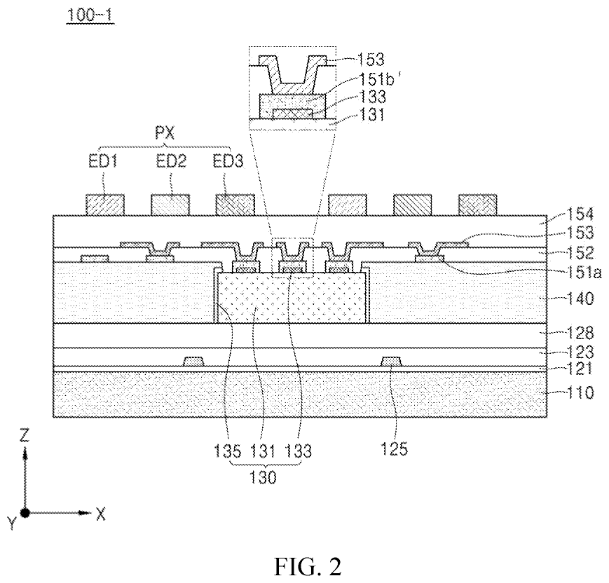

FIG. 2 is a sectional view showing a display apparatus 100-1 according to another embodiment of the present disclosure. The display apparatus 100-1 shown in FIG. 2 is similar to the display apparatus 100 shown in FIG. 1, and can be characterized to have pad contact layers 151b′ disposed on the plurality of pads 133 of the pixel driver chip 130, which is different from the pad contact layer 151b of the the display apparatus 100. Since the configuration of the display apparatus 100-1 of FIG. 2 is the same as or can be similar to the configuration of the display apparatus 100 of FIG. 1 except for the configuration of the pad contact layer 151b′, the description of the display apparatus 100-1 will be focused on the pad contact layer 151b′.

Referring to FIG. 2, the first wires 151a can be disposed on the planarization layer 140. The pad contact layers 151b′ can be disposed on the plurality of pads 133 of the pixel driver chip 130. The pad contact layers 151b′ directly disposed on the plurality of pads 133 can cover side surfaces and top surfaces of the plurality of pads 133. For instance, the pad contact layer 151b′ covers the top and side surfaces of the plurality of pads 133 and directly contacts the upper surface of the element layer 131. The pad contact layers 151b′ directly disposed on the plurality of pads 133 can have a larger size than the plurality of pads 133.

The second wires 153 can be disposed on the pad contact layers 151b′. For instance, a top width of the pad contact layer 151b′ can be greater than a bottom width of the second wire and/or a top width of the pad 133.

The first wires 151a and the pad contact layers 151b′ each can be a single-layer or multi-layer structure of Ti, Ta, Al, Cu, TiN, TaN or the like or a combination thereof. The first wires 151a and the pad contact layers 151b′ each can be a Ti/Al/Ti structure, for example.

FIGS. 3 to 12 are plane views and cross-sectional views showing a manufacturing method of the display apparatus according to an embodiment of the present disclosure. FIGS. 3, 5, 7, 9 and 11 are plane views showing a manufacturing method of a display apparatus according to an embodiment of the present disclosure, whereas FIGS. 4, 6, 8, 10 and 12 are cross-sectional views showing a manufacturing method of a display apparatus according to an embodiment of the present disclosure.

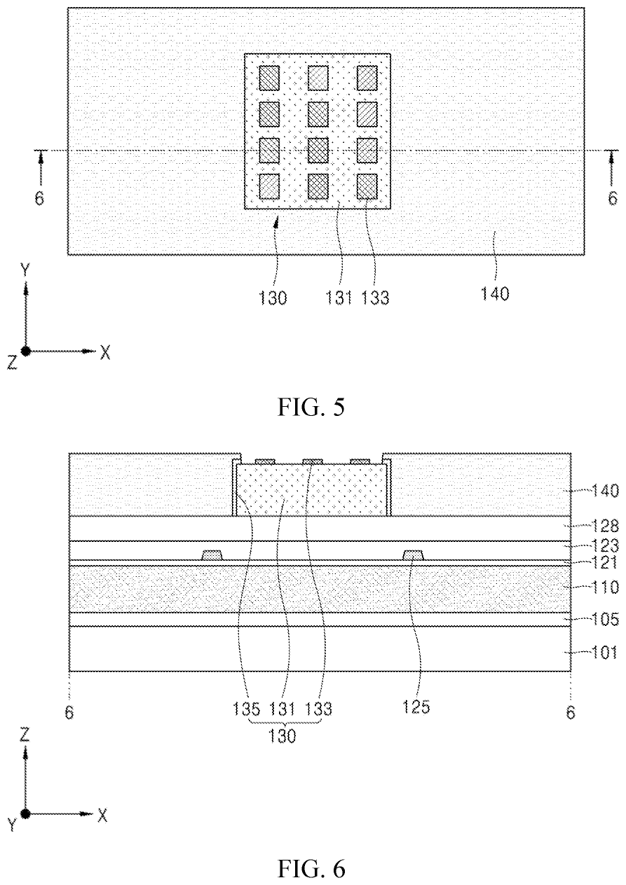

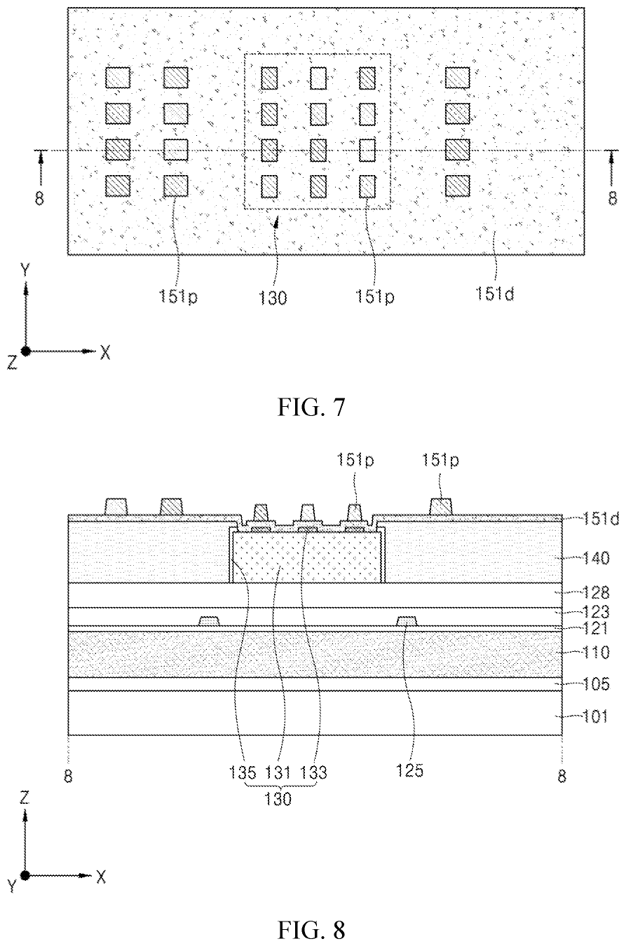

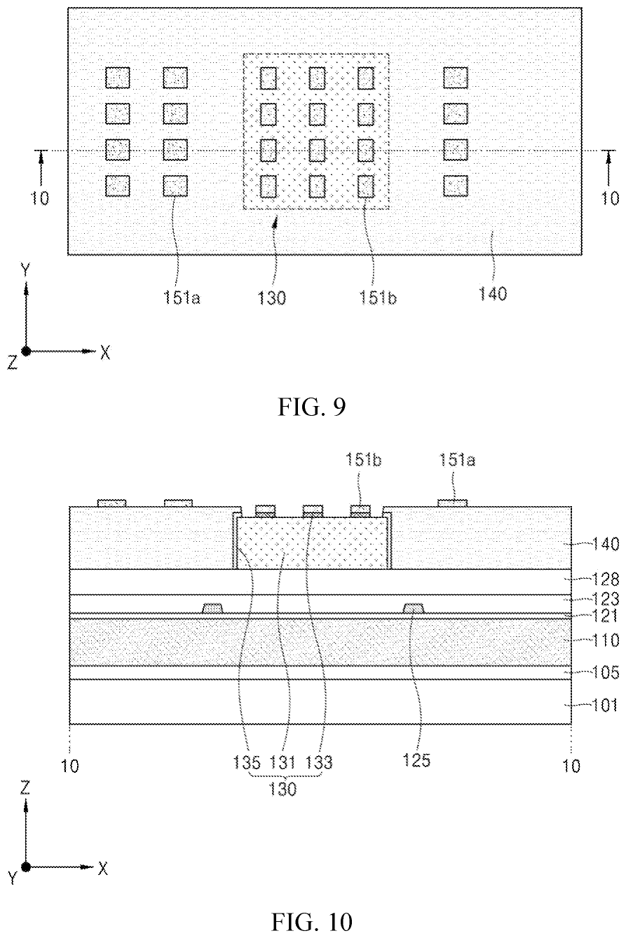

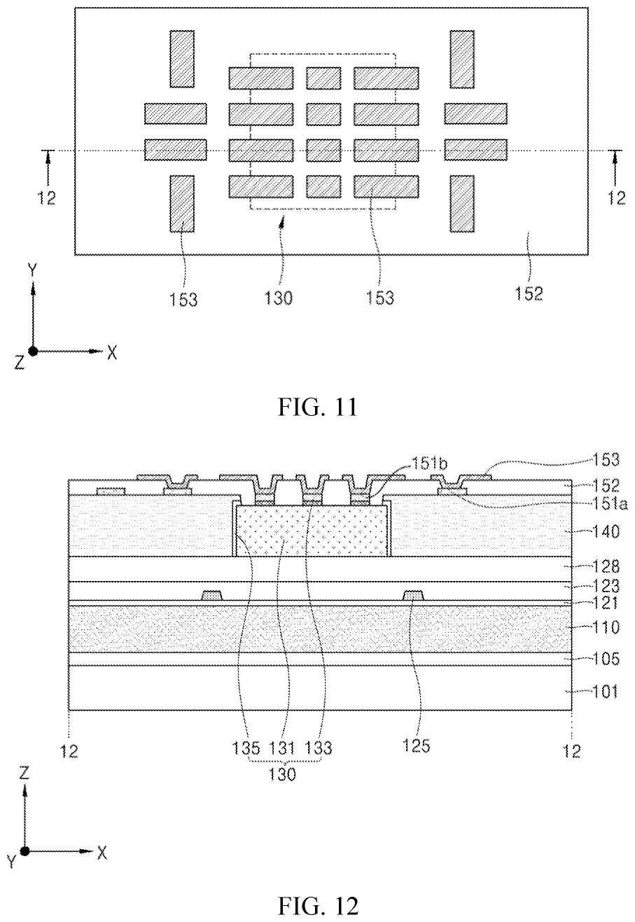

Particularly, FIG. 4 is a cross-sectional view cut along line 4-4 in FIG. 3, FIG. 6 is a cross-sectional view cut along line 6-6 in FIG. 5, FIG. 8 is a cross-sectional view cut along line 8-8 in FIG. 7, FIG. 10 is a cross-sectional view cut along line 10-10 in FIG. 9, and FIG. 12 is a cross-sectional view cut along line 12-12 in FIG. 11. FIGS. 9-12 can be directed to the display apparatus of FIG. 1 but the steps therein can be modified to form the display apparatus of FIG. 2.

Referring to FIGS. 3 and 4, a sacrificial layer 105 can be disposed on a carrier substrate 101, and a substrate 110 can be disposed on the sacrificial layer 105. A first buffer layer 121, alignment marks 125 and a second buffer layer 123 can be formed on the substrate 110. For example, the first buffer layer 121 and the second buffer layer 123 can be made of an insulating material such as silicon nitride, silicon oxide or silicon oxynitride, but the embodiment is not limited thereto. For example, the alignment marks 125 can be made of metal but the embodiment is not limited thereto.

An adhesive layer 128 can be formed on the second buffer layer 123. For example, the adhesive layer 128 can be made of acryl resin, silicon resin or the like, the embodiment is not limited thereto.

The pixel driver chip 130 manufactured by a separate manufacturing process can be disposed on the adhesive layer 128 by a transfer process. The pixel driver chip 130 can be disposed at a predesigned position set by the alignment marks 125. The pixel driver chip 130 can include an element layer 131, a plurality of pads 133 and a passivation film 135. The passivation film 135 can cover the side surfaces of the element layer 131 and the plurality of pads 133. The plurality of pads 133 can have a Ti/TiN/Ti structure, for example. The passivation film 135 can be made of oxide aluminum AlOx, but the embodiment is not limited thereto.

The planarization layer 140 can be formed to surround the side surfaces of the pixel driver chip 130 and disposed on the adhesive layer 128. The planarization layer 140 can cover an edge area of the upper surface of the pixel driver chip 130. The planarization layer 140 can be made of an organic material. For example, the planarization layer 140 can be made of a photosensitive photo acryl or photosensitive polyimide, but the embodiment is not limited thereto.

Referring to FIGS. 5 and 6, a predetermined area of the passivation film 135 can be removed so that the plurality of pads 133 can be exposed. The passivation film 135 can be removed by a wet etching process using a phosphoric acid solution. For instance, the pads 133 as well as portions of the upper surface of the element layer can be exposed. The pads 133 can be arranged in a matrix configuration but can be arranged in a different configuration and/or can have a different shape.

Referring to FIGS. 7 and 8, a conductive material layer 151d covering the planarization layer 140 and the pixel driver chip 130 can be deposited, and photoresist patterns 151p can be formed on the conductive material layer 151d on the planarization layer 140 and the plurality of pads 133. The size of the photoresist patterns 151p formed on the plurality of pads 133 can be equal to that of the plurality of pads 133. In an embodiment, the size of the photoresist patterns 151p formed on the plurality of pads 133 can be greater than that of the plurality of pads 133. The conductive material layer 151d can have a single-layer or multi-layer structure of Ti, Ta, Al, Cu, TiN, TaN or the like or a combination thereof. For example, the conductive material layer 151d can have a Ti/Al/Ti structure. The photoresist patterns 151p can include a first photoresist pattern 151p for forming the first wires 151a and a second photoresist pattern 151p for forming the pad contact layer 151b (or 151b′), both to be formed in FIG. 10. The first and second photoresist patterns can be the same or different from each other. For instance, a bottom width of the first photoresist pattern 151p can be larger than a bottom width of the second photoresist pattern 151p.

Referring to FIGS. 9 and 10, the first wires 151a on the planarization layer 140 as well as the pad contact layer 151b on the plurality of pads 133 can be formed by etching the conductive material layer 151d through a dry etching process using the photoresist pattern 151p. For instance, the first wires 151a and the pad contact layers 151b (or 151b′) can be simultaneously formed by dry etching the conductive material layer 151d.

In FIGS. 7 and 8, the plurality of pads 133 may not be directly exposed in the dry etching process for forming the first wires 151a by forming the photoresist patterns 151p and the conductive material layer 151d, with the same or greater size than the pads 133 (e.g., for covering the pads 133 completely), on the plurality of the pads 133 in advance. Accordingly, any damage to the plurality of pads 133 due to the dry etching process for forming the first wires 151a can be prevented or avoided.

The dry etching process can be performed by using plasma of etching gas including BCl₃ gas and Cl₂ gas.

Referring to FIGS. 11 and 12, a first insulating layer 152 can be formed to cover the planarization layer 140, the pixel driver chip 130 and the first wires 151a. For example, the first insulating layer 152 can be formed on the planarization layer and between the first wires 151a and the pad contact layer 151b. The first insulating layer 152 can be made of photosensitive photo acryl or photosensitive polyimide, but the embodiment is not limited thereto.

Further, second wires 153 can be formed on the first insulating layer 152 to be connected with the first wires 151a through the first insulating layer 152. For instance, the second wires 153 can be in direct contact with the first wires 151a and the pad contact layer 151b (or 151b′). The second wires 153 can be formed by a deposition process of a conductive material layer, a photolithography process and an etching process. The second wires 153 can have a single-layer or multi-layer structure of Ti, Ta, Al, Cu, TiN, TaN or the like or a combination thereof. For example, the second wires 153 can have a Ti/Al/Ti structure. The second wires 153 can have any suitable shape or configuration to provide electrical connection as needed.

Referring to FIG. 1, a second insulating layer 154 can be formed to cover the second wires 153, and light emitting elements ED1, ED2 and ED3 can be disposed or formed on the second insulating layer 154.

Hence, the carrier substrate 101 and the sacrificial layer 105 can be removed. For instance, the carrier substrate 101 and the sacrificial layer 105 can be removed before or after the light emitting elements are formed.

According to the embodiments of the present disclosure, at least the following advantages can be achieved.

In one aspect, the input/output pads of the pixel driver chip may not be damaged during a dry etching process for forming wires on a planarization layer in the display apparatus.

In another aspect, the photolithography process for removing the passivation film of the pixel driver chip can be omitted, thereby simplifying the manufacturing process of the display apparatus and reducing the manufacturing cost.

The display apparatus and the manufacturing method of the same according to the embodiments of the present disclosure can be described as follows.

The display apparatus according to the embodiments of the present disclosure can include a substrate: an adhesive layer disposed on the substrate; a pixel driver chip disposed on the adhesive layer and comprising a plurality of pads disposed on an upper surface thereof; a planarization layer surrounding side surfaces of the pixel driver chip; pad contact layers disposed on a plurality of pads of the pixel driver chip; and first wires disposed on the planarization layer. Here, the pad contact layers and the first wires can have the same thickness and can be configured of the same conductive material layer.

According to several embodiments of the present disclosure, the pad contact layers and the first wires can each have a Ti/Al/Ti multi-layer structure.

According to several embodiments of the present disclosure, the pad contact layers can have the same size (e.g., same width) as the plurality of pads.

According to several embodiments of the present disclosure, the pad contact layers can have a size (e.g., width) greater than the plurality of pads.

According to several embodiments of the present disclosure, the display apparatus can further include an insulating layer covering the pad contact layers and the first wires; and second wires connected to the pad contact layers and the first wires via the insulating layer.

According to several embodiments of the present disclosure, the sum of the thicknesses of the pad contact layers and the second wires disposed on each pad can be 1,000 nm to 1,800 nm.

According to several embodiments of the present disclosure, the display apparatus can further include light emitting elements connected with the pixel driver chip.

According to several embodiments of the present disclosure, the light emitting elements can be inorganic light emitting diodes.

According to several embodiments of the present disclosure, the light emitting elements can be organic light emitting diodes.

The manufacturing method of the display apparatus according to the embodiments of the present disclosure can include forming an adhesive layer on a substrate; mounting a pixel driver chip comprising a plurality of pads on the adhesive layer; forming a planarization layer surrounding side surfaces of the pixel driver chip; depositing a conductive material layer on the planarization layer and the pixel driver chip; and simultaneously forming pad contact layers disposed on the plurality of pads of the pixel driver chip and first wires disposed on the planarization layer by patterning the conductive material layer.

According to several embodiments of the present disclosure, the conductive material layer can each have a Ti/Al/Ti multi-layer structure.

According to several embodiments of the present disclosure, the pad contact layers and the first wires can each have a thickness of 500 nm to 900 nm.

According to several embodiments of the present disclosure, the pad contact layers can have the same size as the plurality of pads.

According to several embodiments of the present disclosure, the pad contact layers can have a size greater than the plurality of pads.

According to several embodiments of the present disclosure, the manufacturing method of the display apparatus can further include forming an insulating layer covering the pad contact layers and the first wires; and forming second wires connected with the pad contact layers and the first wires via the insulating layer.

According to several embodiments of the present disclosure, the sum of the thicknesses of the pad contact layers and the second wires disposed on each pad can be 1,000 nm to 1,800 nm.

According to several embodiments of the present disclosure, the manufacturing method of the display apparatus can further include forming light emitting elements connected with the pixel driver chip.

According to several embodiments of the present disclosure, the light emitting elements can be inorganic light emitting diodes.

According to several embodiments of the present disclosure, the light emitting elements can be organic light emitting diodes.

According to several embodiments of the present disclosure, a display apparatus can include at least one pixel including a plurality of light emitting elements disposed on a substrate; a pixel driver chip disposed on the substrate, and configured to drive the plurality of light emitting elements, wherein the pixel driver chip includes: an element layer disposed on the substrate and including at least one circuit element used to drive at least one of the plurality of light emitting elements, and a plurality of pads disposed on the element layer; a plurality of pad contact layers disposed on the plurality of pads, and corresponding to the plurality of pads; a plurality of first conductive patterns disposed adjacent to the plurality of pad contact layers, and being made of a same material as the plurality of pad contact layers; and a plurality of second conductive patterns connected to the plurality of first conductive patterns and the plurality of pad contact layers for providing electrical connection between the pixel driver chip and the plurality of light emitting elements.

Although the present invention has been described with reference to the exemplified drawings, it is to be understood that the present invention is not limited to the embodiments and drawings disclosed in this specification, and those skilled in the art will appreciate that various modifications are possible without departing from the scope and spirit of the present invention. Further, although the operating effects according to the configuration of the present invention are not explicitly described while describing an embodiment of the present invention, it should be appreciated that predictable effects are also to be recognized by the configuration.

What is claimed is:

1. A display apparatus comprising:
an adhesive layer disposed on a substrate;
a pixel driver chip disposed on the adhesive layer and including a plurality of pads disposed on an upper surface thereof;
a planarization layer surrounding side surfaces of the pixel driver chip;
a plurality of pad contact layers disposed on the plurality of pads of the pixel driver chip; and
a plurality of first wires disposed on the planarization layer,
wherein the plurality of pad contact layers and the plurality of first wires have a same thickness and are made of a same conductive material layer.

2. The display apparatus of claim 1, wherein each of at least one of the plurality of pad contact layers and the plurality of first wires has a Ti/Al/Ti multi-layer structure.

3. The display apparatus of claim 1, wherein at least one of the plurality of pad contact layers has a same size as at least one of the plurality of pads.

4. The display apparatus of claim 1, wherein at least one of the plurality of pad contact layers has a size greater than at least one of the plurality of pads.

5. The display apparatus of claim 1, further comprising:
an insulating layer covering portions of the plurality of pad contact layers and the plurality of first wires; and
a plurality of second wires respectively connected to the plurality of pad contact layers and the plurality of first wires.

6. The display apparatus of claim 5, wherein a sum of thicknesses of the plurality of pad contact layers and the plurality of second wires disposed on each pad is about 1,000 nm to about 1,800 nm.

7. The display apparatus of claim 1, further comprising:
a plurality of light emitting elements electrically connected with the pixel driver chip.

8. The display apparatus of claim 7, wherein the plurality of light emitting elements are inorganic light emitting diodes.

9. The display apparatus of claim 7, wherein the plurality of light emitting elements are organic light emitting diodes.

10. A method for manufacturing a display apparatus, the method comprising:
forming an adhesive layer on a substrate;
forming a pixel driver chip including a plurality of pads on the adhesive layer;
forming a planarization layer to surround side surfaces of the pixel driver chip;
depositing a conductive material layer on the planarization layer and the pixel driver chip; and
simultaneously forming a plurality of pad contact layers on the plurality of pads and a plurality of first wires on the planarization layer by patterning the conductive material layer.

11. The method of claim 10, wherein the conductive material layer has a Ti/Al/Ti multi-layer structure.

12. The method of claim 10, wherein at least one of the plurality of pad contact layers has a same size as at least one of the plurality of pads.

13. The method of claim 10, wherein at least one of the plurality of pad contact layers has a size greater than at least one of the plurality of pads.

14. The method of claim 10, further comprising:
forming an insulating layer covering portions of the plurality of pad contact layers and the plurality of first wires; and
forming a plurality of second wires connected with the plurality of pad contact layers and the plurality of first wires.

15. The method of claim 10, further comprising:
forming a plurality of light emitting elements electrically connected with the pixel driver chip.

16. The method of claim 15, wherein the plurality of light emitting elements are inorganic light emitting diodes.

17. The method of claim 15, wherein the plurality of light emitting elements are organic light emitting diodes.

18. The method of claim 14, wherein a sum of thicknesses of the plurality of pad contact layers and the plurality of second wires disposed on each pad is about 1,000 nm to about 1,800 nm.

19. A display apparatus comprising:
at least one pixel including a plurality of light emitting elements disposed on a substrate;
a pixel driver chip disposed on the substrate, and configured to drive the plurality of light emitting elements, wherein the pixel driver chip includes:
an element layer disposed on the substrate and including at least one circuit element used to drive at least one of the plurality of light emitting elements, and a plurality of pads disposed on the element layer;
a plurality of pad contact layers disposed on the plurality of pads, and corresponding to the plurality of pads;
a plurality of first conductive patterns disposed adjacent to the plurality of pad contact layers, and being made of a same material as the plurality of pad contact layers; and
a plurality of second conductive patterns connected to the plurality of first conductive patterns and the plurality of pad contact layers for providing electrical connection between the pixel driver chip and the plurality of light emitting elements.

20. The display apparatus of claim 19, wherein a width of at least one of the plurality of pad contact layers corresponds to a width of at least one of the plurality of pads and/or a bottom width of at least one of the plurality of second conductive patterns.

21. The display apparatus of claim 19, wherein a width of at least one of the plurality of pad contact layers is greater than a width of at least one of the plurality of pads.

22. The display apparatus of claim 19, wherein the plurality of first conductive patterns and the plurality of pad contact layers are formed simultaneously by patterning the same material covering the pixel driver chip.
